(19) United States
(12) Patent Application Publication
(10) Pub. No.: US 2007/0035936 A1
(43) Pub. Date: Feb. 15, 2007

(54) Cover structure

(75) Inventor: Chih-Peng Chuang, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/394,977

(22) Filed: Mar. 30, 2006

(30) Foreign Application Priority Data
Aug. 12, 2005 (TW) 094213803

(51) Int. Cl. H05K 7/14

(52) U.S. Cl. 361/801

(57) ABSTRACT

A cover structure for protecting an unoccupied portion of an electronic device is proposed. The cover structure includes: a main body portion formed with a first leaf body for covering the surface of the electronic device, and a second leaf body formed surrounding the periphery of the first leaf body, wherein the first leaf body is at least formed with a first opening; at least an active member; and at least a fastening member disposed on the second leaf body, wherein the active member is related to the fastening member such that the fastening member is actuated along with the action of the active member, allowing a user to concurrently operate on the first opening of the first leaf body and the active member to install or remove the cover structure to or from the unoccupied portion of the electronic device as needed.

### FIELD OF THE INVENTION

The present invention relates to cover assemblies, and more particularly, to a cover structure for protecting an unoccupied portion of an electronic device against contamination.

### BACKGROUND OF THE INVENTION

As a result of rapid technological progress, electronic products that are capable of integrating a variety of functions and services have become a mainstream in the market. A variety of cover assemblies to which electronic components can be attached are known and used. It would be desirable if a cover assembly or apparatus could function as a secure cover for an unoccupied portion of an electronic device to protect electronic components contained therein against contamination.

FIG. 1 shows a conventional power supply apparatus 20 that is applicable to electronic products such as servers to supply power as required, wherein the power supply apparatus 20 is comprised of a variety of semiconductor devices and electronic components to facilitate operation. Often, a power supply unit reserves some space in the form of an empty bay to add additional components to enhance the capacity or functionality; consequently, an unoccupied portion 200 is commonly employed to connect the surface of the power supply apparatus 20 to thereby protect the machine unit from outside contaminants or damage via the unoccupied portion 200. Conventionally, a cover structure 10 is installed on the surface of the power supply apparatus 20 that corresponds to the unoccupied portion 200, thereby covering the unoccupied portion 200 to prevent outside contaminants from entering the machine.

The cover structure 10 primarily consists of a metal box body, which is connected to the power supply apparatus 20 substantially by means of elasticity of a plurality of metal spring leafs 11 that are formed on one or more sides of the box body to connect with the walls of the unoccupied portion 200 of the power supply apparatus 20. Furthermore, a portion of the exposed surface of the box body in its installed position is formed with an opening 12, allowing a user to place a finger therein that facilitates insertion and removal of the cover structure lo from the unoccupied portion 200 of the power supply apparatus 20.

However, one drawback of using the elasticity of the metal spring leafs to connect the cover structure to the power supply apparatus is that it often does not provide sufficient gripping and is prone to shifting by vibration or external forces and thus easily becomes detached as a result.

Another example of a common cover structure is shown in FIG. 2, in which one or more tabbed spring leaves 13 are formed on one or more sides of the box body of the cover structure 10, and one or more corresponding openings (not shown) are formed on the walls bounding the unoccupied portion corresponding to the power supply apparatus, such that each tabbed spring leaf 13 formed on the cover structure 10 can be snapped into a corresponding opening of the power supply apparatus to thereby fasten the cover structure onto the unoccupied portion of the power supply apparatus.

By using the combination of tabbed spring leaves and openings, a cover structure is effectively connected to a power supply apparatus to overcome the foregoing drawback of easy detachment caused by using merely the elasticity of metal spring leaves that are prone to shifting with vibration and external forces. While the cover structure can be tightly connected to the power supply apparatus by means of tabbed spring leaves, the method is troublesome and inconvenient to implement.

Therefore, there exists a need to provide a novel cover structure capable of functioning as a secure cover for an unoccupied portion of an electronic device while it is also easy and convenient to operate.

### SUMMARY OF THE INVENTION

In light of the drawbacks mentioned above, a primary objective of the present invention is to provide a cover structure that functions as a secure cover for protecting an unoccupied portion of an electronic device.

Another objective of the present invention is to provide a cover structure that can be effectively and tightly fastened on an electronic device.

Another objective of the present invention is to provide a cover structure that can allow convenient operation with respect to an electronic device for the user.

In accordance with the above and other objectives, the present invention discloses a cover structure for protecting an unoccupied portion of an electronic device. The cover structure comprises: a main body portion including a first leaf body for covering the surface of the electronic device, and a second leaf body disposed and surrounded the periphery of the first leaf body and may be extended into the electronic device, wherein the first leaf body is formed with at least a first opening; at least an active member disposed on the first leaf body; at least a fastening member disposed on the second leaf body, wherein the active member is related to the fastening member such that the fastening member is actuated along with the action of the active member to enable the cover structure to attach to or detach from the electronic device via the fastening member, thereby allowing a user to concurrently operate the first opening of the first leaf body and the active member to install or remove the cover structure from the unoccupied portion of the electronic device, if needed. In addition, the second leaf body may further include at least a spring leaf to strengthen the connection between the cover structure and the electronic device.

The active member and the fastening member of the present invention may be integrally constituted by an elastic member, wherein one end of the elastic member is the active member and another end of the elastic member is fastened to an inner side of the second leaf body of the main body portion, and a middle portion of the elastic member is the fastening member, designed to allow a user to move the active member disposed at one end of the elastic member to actuate the related fastening member located at the middle portion of the elastic member, thereby enabling the cover structure to connect with or detach from the electronic device as needed. Further, a user may use a finger to extend into the opening of the first leaf body of the cover structure in order to connect or remove the cover structure from the unoccupied portion of the electronic device.

The cover structure of the invention is implemented by actuating an active member of the first leaf body with a user's finger, and the motion of the active member in turn actuates a related fastening member to enable a tight connection or easy detachment of the cover structure from an electronic device. Alternatively, a user's finger may reach into the opening of the first leaf body of the cover structure to conveniently connect or remove the cover structure from the unoccupied portion of the electronic device.

To provide a further understanding of the invention, the following detailed description illustrates embodiments of the invention, it being understood that this detailed description is being provided only for illustration of the invention and not as limiting the scope of this invention.

### BRIEF DESCRIPTION OF THE DRAWINGS

Detailed description of embodiments of the invention will be made with reference to the accompanying drawings, wherein:

FIG. 1 (PRIOR ART) is a schematic view showing a conventional power supply apparatus and a cover assembly;

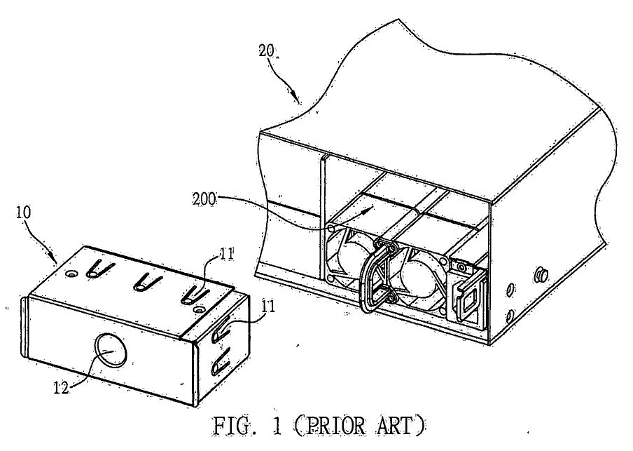

FIG. 2 (PRIOR ART) is another schematic view of a prior art cover structure;

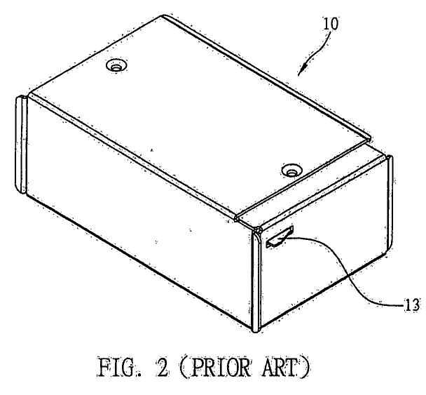

FIG. 3 is a schematic view showing the cover structure for protecting an unoccupied portion of an electronic device according to the present invention;

FIG. 4 is an exploded cross-sectional view of the cover structure according to the present invention; and,

FIG. 5 is a schematic view showing the installed configuration of the cover structure of the present invention and an electronic device.

### DETAILED DESCRIPTION OF THE PREFERRED EMBODIMENTS

Reference will now be made in detail to the preferred embodiment of the present invention, the advantages and functions of the present invention being readily discernible to those skilled in the art according to the detailed description. The present invention should therefore cover various modifications and variations made to the herein-described structure and operations of the invention, provided that they fall within the scope of the invention.

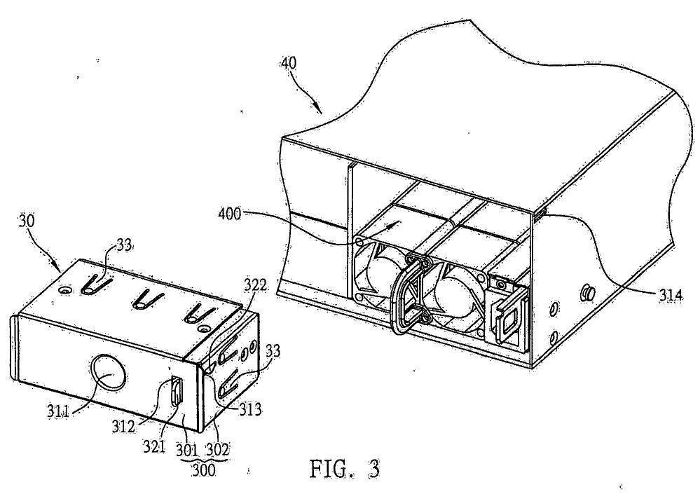

FIG. 3 shows a schematic view of the cover structure applicable to electronic products in accordance with the present invention. Note that the drawings are simplified schematic views intended only for illustrating the basic structure of the invention. Thus, only the parts and elements that are relevant to the invention are shown in the drawings, which are not drawn according to the actual number, shape, and size and could be more complex in practical application.

As shown in FIG. 3, the cover structure 30 is adapted to protect an unoccupied portion 400 of an electronic device 40, wherein the electronic device 40 can be a power supply apparatus or a desktop computer, and so forth.

The cover structure 30 essentially consists of a main body portion 300, which is comprised of at least a first leaf body 301 for covering the electronic device 40, and a second leaf body 302 disposed on the periphery of the first leaf body 301 that extends to the inside of the electronic device 40. The first leaf body 301 is at least formed with a first opening 311 and an opening 312 to receive a first active member 321 disposed on one end of an elastic member 322. The elastic member 322 is disposed on the second leaf body 302 at a point of attachment (not shown) generally located at the end opposite from the first active member 321. The active member 321 is related to the fastening member 322 such that the fastening member 322 is actuated along with the action of the active member 321 that enables the cover structure 30 to attach to or detach from the electronic device 40 via the fastening member 322, thereby allowing a user to concurrently operate on the first opening 311 of the first leaf body 301 and the active member 321 to install or remove the cover structure 30 from the unoccupied portion 400 of the electronic device 40 as needed.

The main body portion 300 of the cover structure 30 can be an open-box structure, wherein the first leaf body 301 constitutes the bottom of the box structure (and the back of the cover structure in application) and the second leaf body 302 constitutes the sides of the box structure. The first leaf body 301 and the second leaf body 302 can be made of metal leaves with elasticity such that they can flex. In addition, the second leaf body 302 of the main body 300 can be formed with an extra spring leaf 33 for strengthening the attachment between the cover structure 30 and the electronic device 40.

The first opening 311 formed on the first leaf body 301 is provided to allow insertion of a user's finger to conveniently install or remove the cover structure 30 from the unoccupied portion 400 of the electronic device 40.

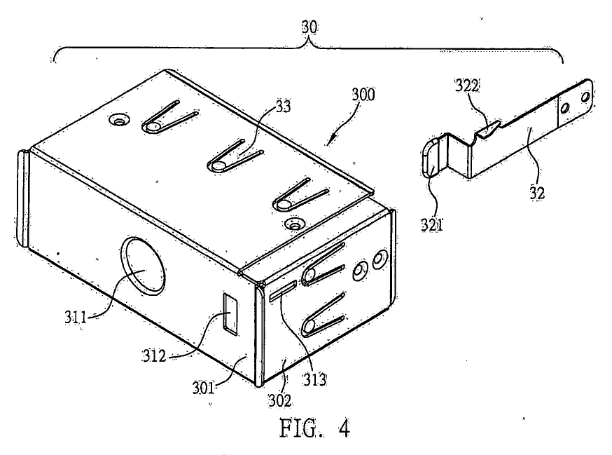

FIG. 4 is an exploded view showing the active member 321 and the fastening member 322 of the cover structure 30 according to the invention. In normal circumstances where no external forces are exerted, the active member 321 and the fastening member 322 protrude from the first leaf body 301 and the second leaf body 302, respectively. The active member 321 and the fastening member 322 can be formed integrally by an elastic member 32 made of a metallic or plastic material, wherein one end of the elastic member 32 is the active member 321 and the other end thereof is fastened to an inner side of the second leaf body 302 of the main body 300, a middle portion of the elastic member 32 being the fastening member 322 adapted to allow a user to press down the active member 321 disposed at one end of the elastic member 32, so as to actuate the related fastening member 322 located at the middle portion of the elastic member 32, thereby enabling the cover structure 300 to attach with or detach from the electronic device as needed.

As mentioned, the first leaf body 301 is further formed with a second opening 312 adapted to allow the active member 321 that is disposed at one end of the elastic member 32 to extend outward from the inside of the main body 300 into the second opening 312 of the first leaf body 301. The size of the second opening 312 is larger than that of the active member 321 to allow planar motion of the active member 321 within the second opening 312. Similarly, the second leaf body 302 is further formed with an opening 313 corresponding in position to an opening 314 formed on the surface of the electronic device 40, allowing the fastening member 322 located at the middle portion of the elastic member 32 to extend through the opening 313 of the second leaf body 302 into the opening 314 of the electronic device 40, thereby tightly fastening the cover structure 30 onto the unoccupied portion 400 of the electronic device 40 via the fastening member 322.

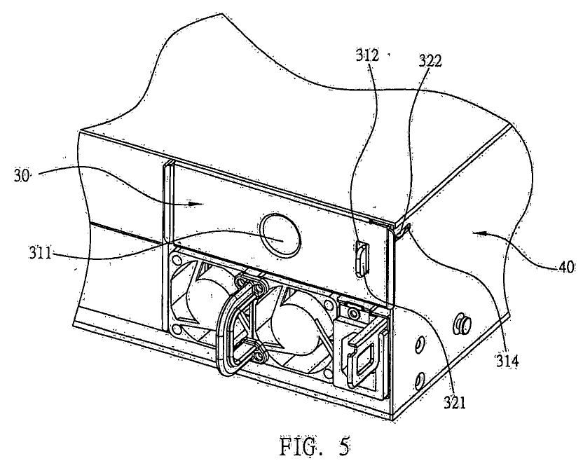

In practical operation, a user's thumb of the right hand reaches into the first opening 311 formed on the first leaf body 301 of the cover structure 30, and, at the same time, the user's index finger of the right hand actuates the active member 321 that is protruding from the second opening 312 of the first leaf body 301 so that pressure from the index finger can planarly move the active member 321 within the second opening 312, such that the fastening member 322 is actuated to retract into the opening 313 of the second leaf body 302, thereby releasing the cover structure 30 from a predetermined position of the unoccupied portion 400 of the electronic device 40. Further, after the user's right hand index finger moves away from the active member 321, the fastening member 322 returns to its original position to resume a protruding state through the opening 313 of the cover structure 30 into the opening 314 of the electronic device 40, as shown in FIG. 5, thereby tightly fastening the cover structure 30 into the unoccupied portion 400 of the electronic device 40.

Summarizing the above, the cover structure of the invention is utilized by actuating an active member protruding through the first leaf body with a user's finger, whose motion, in turn, actuate a fastening member to tightly connect or detach the cover structure from an electronic device as required. Alternatively, a user's finger may extend to reach into the opening of the first leaf body of the cover structure to conveniently connect or remove the cover structure from the unoccupied portion of the electronic device.

It will be understood that the above description of the present invention is susceptible to various modifications, changes, and adaptations, and such similar versions are intended to be comprehended within the meaning and range of equivalents of the appended claims.

What is claimed is:

1. A cover structure for protecting an unoccupied portion of an electronic device, comprising:
a main body portion comprising a first leaf body for covering a surface of the electronic device, and a second leaf body disposed surrounding a periphery of the first leaf body, wherein the first leaf body is formed with at least a first opening;
at least an active member disposed on the first leaf body; and
at least a fastening member disposed on the second leaf body, wherein the active member is related with respect to the fastening member such that the fastening member is actuated along with an action of the active member to enable the cover structure to attach to or detach from the electronic device via the fastening member, allowing a user to concurrently operate the first opening of the first leaf body and the active member to install or remove the cover structure from an unoccupied portion of the electronic device.

2. The cover structure of claim 1, further comprising a spring leaf disposed on the second leaf body of the main body portion.

3. The cover structure of claim 1, wherein the main body portion of the cover structure is a box structure, wherein the first leaf body constitutes the bottom of the box structure and the second leaf body constitutes the sides of the box structure, and the first leaf body and second leaf body are made of metal leaves that are elastic.

4. The cover structure of claim 1, wherein the first opening of the first leaf body is provided to allow insertion of a user's finger therein, so as to conveniently install or remove the cover structure from the unoccupied portion of the electronic device.

5. The cover structure of claim 1, wherein the active member and the fastening member are protruded from the first leaf body and the second leaf body, respectively, in normal circumstances where no external forces are exerted.

6. The cover structure of claim 1, wherein the active member and the fastening member are formed integrally by an elastic member, wherein an end of the elastic member is the active member and an another end thereof is fastened to an inner side of the second leaf body of the main body portion, and a middle portion of the elastic member is the fastening member.

7. The cover structure of claim 6, wherein the first leaf body is further formed with a second opening allowing the active member that is formed at the end of the elastic member to extend outward from the inner side of the main body portion into the second opening of the first leaf body, the size of the second opening being larger than that of the active member to allow planar motion of the active member within the second opening.

8. The cover structure of claim 6, wherein a third opening is formed on the second leaf body and a fourth opening is formed in a surface of the electronic device and in a position corresponding to the third opening, allowing the fastening member located at the middle portion of the elastic member to concurrently extend outward into the third opening of the second leaf body and the fourth opening in the surface of the electronic device, so as to tightly fasten the cover structure to the unoccupied portion of the electronic device via the fastening member.

9. The cover structure of claim 8, wherein the first opening formed on the first leaf body of the cover structure is provided to allow a user's thumb of the right hand to insert therein, and, meanwhile, the user's index finger of the right hand actuates the active member that is protruding from the second opening of the first leaf body so that the active member is moved planarly within the second opening, such that the fastening member is actuated along with the action of the active members and retracted into the third opening of the second leaf body, thereby allowing the cover structure to be installed to a predetermined position of the unoccupied portion of the electronic device, and then, after the user's right hand index finger moves away from the active member, the fastening member protrudes through the third opening of the cover structure into the fourth opening of the electronic device, so as to tightly fasten the cover structure to the unoccupied portion of the electronic device.

10. The cover structure of claim 1, wherein the electronic device is at least one of a power supply unit and a desktop computer.
